(19) United States
(12) Patent Application Publication
(10) Pub. No.: US 2009/0160052 A1
(43) Pub. Date: Jun. 25, 2009

(54) UNDER BUMP METALLURGY STRUCTURE OF SEMICONDUCTOR DEVICE PACKAGE

(75) Inventors: Wen-Kun Yang, Hsin-Chu City (TW); Chin-Lung Yang, Jhudong Township (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 11/959,629

(22) Filed: Dec. 19, 2007

(51) Int. Cl. H01L 23/488

(52) U.S. Cl. 257/738; 257/E23.023

(57) ABSTRACT

The under bump metallization (UBM) structure of semiconductor device comprises a substrate having a bonding pad disposed on an active surface; a UBM adhered on the bonding pad, wherein the UBM includes lateral embedded portions and the size of the UBM is larger than the size of the bonding pad; a dielectric layer over the UBM having opening that is smaller than the size of the UBM so as to allow the lateral embedded portions being embedded into the dielectric layer with a desired dimension; and a conductive ball melted on the UBM within the opening defined by the dielectric layer.

### FIELD OF THE INVENTION

This invention relates to a structure of package, and more particularly to a under bump metallurgy (UBM) structure of package and manufacturing of the same.

### BACKGROUND OF THE INVENTION

### Description of the Prior Art

Typically in the electronic component world, integrated circuits (ICs) are fabricated on a semiconductor substrate, known as a chip, and most commonly are made of silicon. The silicon chip is typically assembled into a larger package which serves to provide effective enlargement of the distance or pitch between input/output contacts of the silicon making it suitable for attachment to a printed circuit board, and to protect the IC from mechanical and environmental damage. With the trend moving to more and more features packed into decreasing product envelopes, utilizing ever smaller electronic components to improve upon size and feature densification a constant and formidable challenge is presented to manufacturers of consumer and related articles.

Chip scale packages (CSP) were developed to provide an alternative solution to directly attached flip chips devices. These packages (CSP) represent a new miniature type of semiconductor packaging used to address the issues of size, weight, and performance in electronic products, especially those for consumer products such as mobile telephones, pagers, portable computers, video cameras, etc. Standards have not yet been formalized for CSP, and as a result, many variations exist, and several of which are described in “Chip Scale Package”, cited above. In general, the chip is the dominant constituent of a CSP with the area of the package, being no more than 20% greater than the area of the chip itself, but the package has supporting features which make it more robust than direct attachment of a flip chip.

As integrated circuits advance toward higher speeds and larger pin counts, and first-level interconnection techniques employing wire bonding technologies have approached or even reached their limits. New improved technologies for achieving fine-pitch wire bonding structures cannot keep pace with the demand resulting from increased IC chip processing speeds and higher IC chip pin counts. As such, the current trend is to replace wire bonding structures with other package structures, such as a flip chip packages and a wafer level packages (WLP).

Some chip bonding technologies utilize a copper bump attached to a contact pad on the chip to make an electrical connection from the chip to the package. For example, new packaging methods include BGA (Ball Grid Array) and CSP (Chip Scale Package) methods where semiconductor chips are mounted on a substrate, such as a printed circuit board. In flip chip bonding, bumps are usually formed beforehand on the bonding pads of a semiconductor chip and the bumps are then interfaced with the terminals located on an interconnect substrate followed by, for example, thermo-compression bonding.

For example, driver chips must be mounted on a glass substrate. A mounting technology known as “chip on glass has emerged as a cost effective technique for mounting driver chips using a flat-top metal bump, for example a copper bump. Copper bumps may be formed by electro-deposition methods of copper over layers of under bump metallization (UBM) formed over the chip bonding pad. The copper bump (column) is typically formed within a mask formed of photo resist or other organic resinous material defining the bump forming area over the chip bonding pad.

In addition, the use of solder bumps in attaching die to flip-chip packaging is well known in the art. As shown therein a die is provided which has an I/O pad or die pad disposed thereon. A photo polymer passivation layer is provided to protect the die from damage during processing. An Under Bump Metallurgy (UBM) structure is disposed on the die pad, and a solder ball is placed or formed on top of the UBM structure. The solder ball is used to form an electrical and mechanical connection between the die and a Printed Circuit Board (PCB) or other device.

Moreover, one significant factor affecting solder joint life is the Under Bump Metallization (UBM) structure employed in conjunction with the solder joint. Rather, existing UBM schemes have been designed to optimize metallurgical or processing parameters rather than to improve the reliability of solder joints. In the conventional package scheme, the tin infiltration will occur, it refers to that the solder will be infiltration through the structure of the UBM to the bonding pads, it is called Inter-Metallurgy Compound (IMC) structure. For example, if the surface of the UBM comprises copper and the solder ball is a tin-lead alloy, the issue will be raised.

FIG. 1 illustrates a conventional conductive ball structure 200. Aluminum bonding pads 202 is formed on a silicon substrate 201. A silicon nitride layer 203 covers the substrate 201 to expose a portion of the bonding pads 202. A slop profile 203a is formed on the edge of the silicon nitride layer 203. A BCB or PI 210 is formed over the silicon nitride layer 203 for isolation. A sputtering metal (UBM) 204 composed of dual layers 205, 206, is formed lying on the surface 210a of the BCB or PI 210 and the aluminum bonding pads 202. A soldering metal 207 is formed within the UBM 204. The contact area dimension between the ball and the UBM is almost the same with the dimension of the UBM. Under the ball shear test, the first tear or peeling will be happen in “A” area as indicated in FIG. 4a, the UBM metal will be peeled off from the surface of dielectric layer as initial point, even the Al pads will be peeled off as well. In some testing result, the metal pads peel off from the Al pads—refer to FIG. 4aa. Based on the materials properties, the adhesion strength will be: Solder ball to metal pad is stronger than Metal pads to Al bonding pads; the strength between metal pads and Al bonding pads is stronger than the one between the metal pads and the dielectric layer (BCB/PI). Further, an tin infiltration issue occurs due to the scheme of the conventional UBM, it is so-called tin infiltration.

In view of the aforementioned drawbacks, a new under bump metallurgy (UBM) structure for package is required and provided by the present invention which can improve the above drawbacks.

### SUMMARY OF THE INVENTION

In view of the drawbacks of prior art, the present invention provides a new under bump metallurgy (UBM) structure of package to improve solder join, the adhesion strength, T/C stress releasing and shear testing.

According to the above-mentioned purpose, there is thus a need for a new UBM structure to promote solder joint reliability, facilitate solder ball placement and enhance the integrity of the mechanical adhesion strength and solder ball joint.

The under bump metallization (UBM) structure of semiconductor device comprises a substrate having a bonding pad disposed on an active surface; a UBM adhered on the bonding pad, wherein the UBM includes lateral embedded portions and the size of the UBM is larger than the size of the bonding pad; a dielectric layer over the UBM having opening that is smaller than the size of the UBM so as to allow the lateral embedded portions being embedded into the dielectric layer with a desired dimension; and a conductive ball melted on the UBM within the opening defined by the dielectric layer.

The structure further comprises a metal seed layer formed under the UBM structure. UBM include a lower layer made of copper-containing layer and an intermediate layer made of nickel-containing layer as barrier layer. An upper layer is made of Au-containing layer. It is preferably the lateral embedded portions of the UBM are longer than 30 μm, and it can be extended to near next solder pads, it also prefers to add the via holes inside the lateral embedded portions of UBM, the largest metal pads and via holes can enhanced the adhesion strength between metal layer and dielectric layer and passivation layer. A passivation layer is covered over the substrate to expose the bonding pad. The material of the passivation layer includes BCB, PI or silicon nitride. The material of the dielectric layer includes BCB, PI, SINR (Siloxane polymer) or solder mask. In general, it is preferred to choice the materials with better adhesion with each other.

Moreover, the dielectric layer maybe a stress compensation layer (SCL), and material of the dielectric layer comprises BCB, SINR (Siloxane polymer), epoxy, PI (polyimide) or silicone rubber resin. The thickness of the dielectric layer is about 5 micron to 50 micron, it will depends on the materials to be used to enhance the adhesion strength. Material of the metal seed layer comprises Ti, Ti—W, Ti—N, TiW or Ta, TaN alloys. The metal seed layer and Cu seed layer is formed by employing a sputtering process. The thickness of the metal seed layer and Cu seed layer together is about 0.3 micron to 1 micron.

### BRIEF DESCRIPTION OF THE DRAWINGS

The above objects, and other features and advantages of the present invention will become more apparent after reading the following detailed description when taken in conjunction with the drawings, in which:

FIG. 1 is a schematic diagram of under bump metallurgy structure of package according to the prior art.

FIG. 2 is a top view of the under bump metallurgy structure of package according to the present invention.

FIG. 3 is a schematic diagram of under bump metallurgy structure of package according to the present invention.

FIGS. 4a, 4aa are the under bump metallurgy structure of package under shear force testing according to the prior art.

FIG. 4b is the under bump metallurgy structure of package under shear force testing according to the present invention.

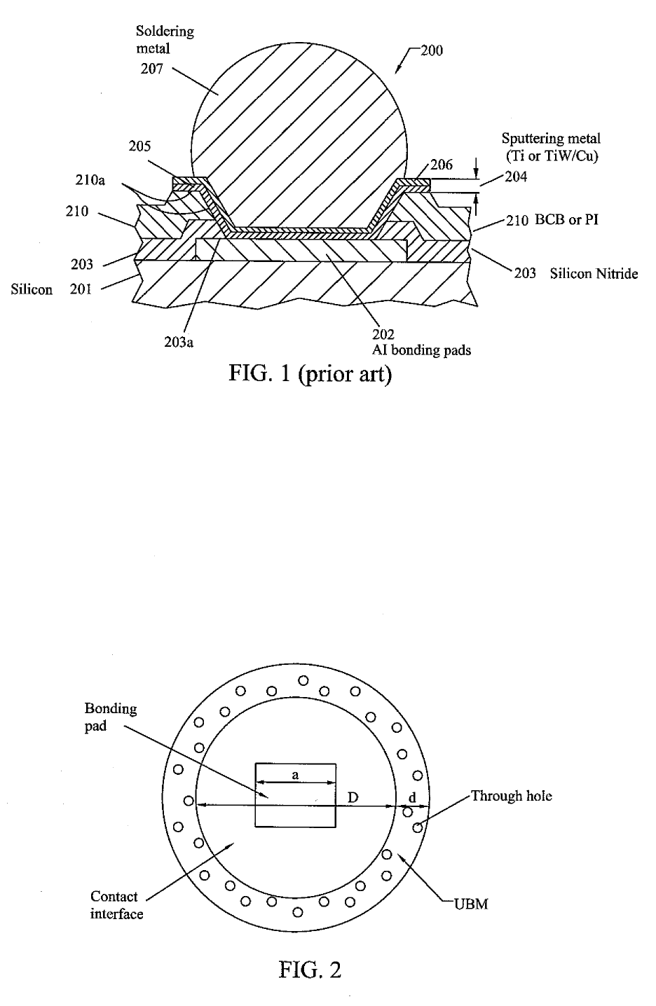

### DESCRIPTION OF THE PREFERRED EMBODIMENT

The present invention discloses a under bump metallurgy structure of package and method of the same. It can apply to a wafer level package. Some sample embodiments of the invention will now be described in greater detail. Nevertheless, it should be recognized that the present invention can be practiced in a wide range of other embodiments besides those explicitly described, and the scope of the present invention is expressly not limited expect as specified in the accompanying claims.

A new Under Bump Metallization (UBM) layer is disclosed herein which is especially suitable for use with a Wafer Level Chip Scale Package (WLCSP). The UBM dramatically improves package lifetime, and improve the peeling effect caused by the prior art structure.

The mechanical properties of the solder joint further improved by providing a larger area of contact between the material of the UBM and the dielectric material, thereby improving the integrity of the dielectric layer—UBM interface—enhanced the adhesion strength due to the lateral embedded portions of the UBM are stuck and adhered by the dielectric layer from bottom and top side, it also prefers to add the via holes inside lateral embedded portion of UBM (not show in the drawing) that will offer stronger adhesion strength. In the case or prior art, the inter-diffusion of these materials diminishes the likelihood of solder fatigue along the interface.

Of course, this procedure may be modified slightly through appropriate definition of the photo resist if a UBM structure is desired. It is understood that many variations of this embodiment exist. This particular methodology is useful for forming solder bumps on a device designed for WL-CSP application, a situation that often requires redistribution of the bond pads.

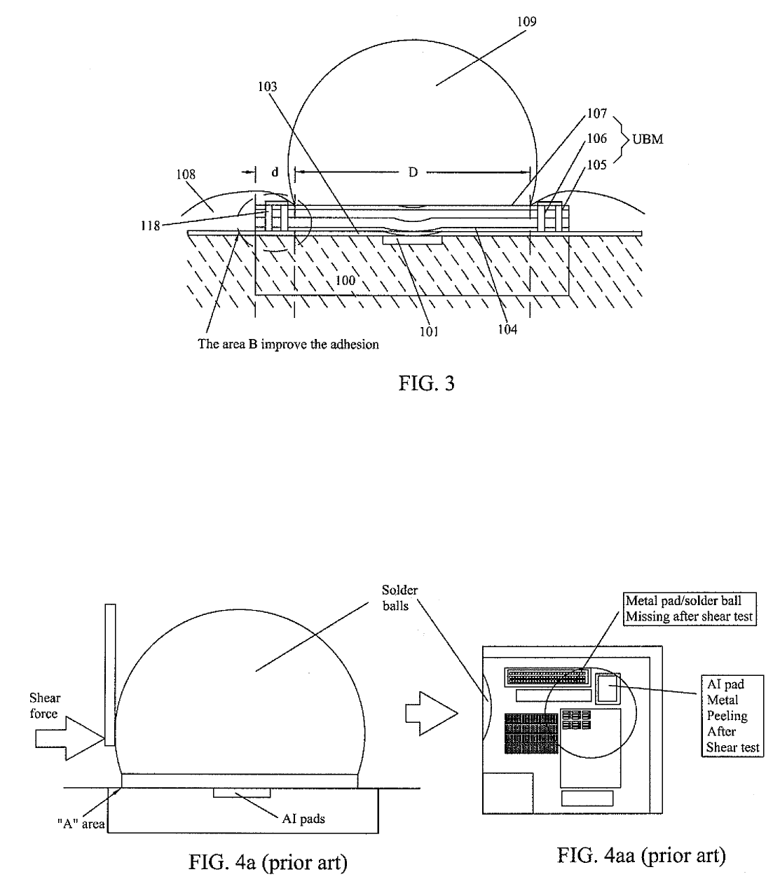

With reference to FIG. 3, a semiconductor substrate 100 having bond pads 101 thereon is provided. In order to provide for proper placement and pitch of the solder bumps that are to be introduced at a later stage, the metal bond pads could be redistributed to form the redistributed layer (RDL). The RDL could be optional element. In the present invention, the redistributed layer is not shown in the figure. It may comprise a first layer of copper or copper alloy and a second layer of aurum or aurum alloy.

A dielectric (passivation) layer 103 is formed over the substrate 100 to expose a portion of the bonding pads 102. A metal seed layer 104 is subsequently formed by Ti/Cu. Next, the UBM is formed over the sputtering seeding metal 104, followed by patterning the UBM. The sputtering metal 104 is typically formed by Ti/Cu, and the UBM is composed by three sub-layers including the lower layer (Cu) 105, intermediate layer (Ni) 106 and upper layer (Al) 107.

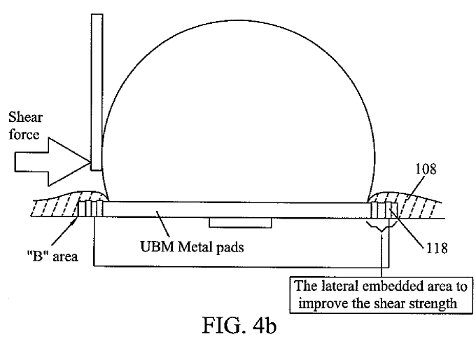

A dielectric layer 103, which may be, for example, a material such as silicon nitride, BCB, SINR (Siloxane polymer), epoxy, PI (polyimide). A further dielectric layer 108 is then formed over the UBM and the edges of the UBM is embedded into the dielectric layer 108. It means that the edges of the UBM are collaterally extended into the dielectric layer 108 with a desired dimension by controlling the opening of the dielectric layer 108 as indicted by “B” area of FIG. 3. The collateral embedded portions B will increase the adhesion strength. If the contact dimension “D” refers to the contact interface between the ball 109 and the UBM, then the length “d” of the collateral embedded portions “B” is extended from the contact interface edge of the ball to the edge of the UBM. The dielectric layer 108 may be formed by printing or employing a photolithography process and an etching process. (D+2d) is equal to the width or length of the UBM. It may be BCB, PI (polymer materials), or solder mask. Please refer to FIG. 2, it illustrates the top view of the scheme of the present invention. The Al bonding pads area=a×a (normally is 80 μm×80 μm=6400 micron-meter square). Solder metal pads open area=3.14×[(D/2)]². For 0.3 mm diameter solder balls, the open area is, for example, 70650 μm square. Metal pads area=3.14×[(D/2)+d]². Assume d>50 μm, than, the metal pads size is 125600 μm square. It means that the adhesion size of metal pads (to silicon nitride, PI, BCB) will be stronger than the one between the solder balls and metal, refer the FIG. 4b vs. FIG. 4a. It is also stronger than the adhesion of metal pads adhesion to Al pads. 125600-70650=54950, so, it will increase at least ⅔ adhesion strength to improve the ball shear, as shown in FIG. 4b. For large metal pads, during ball shear test, The first tear or peeling area will be either the solder balls near to metal pads area or the “B” area, and the overall ball shear strength will be much higher than prior art. The extended area B will improve the shear strength, preferably, the d>30 um and it can be extended to near the pitch between next metal pads, it maybe preferred to make a plurality of via through holes 118 inside lateral embedded portions of UBM metal layers 105, 106, 107 that located inside the “B” area that allow the dielectric layer 108 be filled into the through holes and adhesion together with the dielectric layer 103, this kind of structure will also increase the adhesion strength.

In this approach, the shape of the UBM (larger size with several via through holes in “B” area) is defined primarily before the patterned dielectric layer 108. In one example, the dielectric layer 108 may be employed as a stress compensation layer (SCL). For example, the dielectric layer 108 typically has a layer thickness within the range of about 15 micron to about 50 micron, preferably within the range about 25 micron to about 35 micron. In the SCL embodiment, the layer 108 comprises an epoxy, a diluent, a filler, and a photoinitiator. The epoxy is preferably an aromatic epoxy such as bisphenol A diepoxide or bisphenol F diepoxide. Useful fillers include, for example, borosilicate glass, quartz, silica, and spherical glass beads. Useful diluents include, for example, aliphatic epoxies or cycloaliphatic epoxies which have a lower index of refraction than the aromatic epoxy being used. Thus, for example, if bisphenol F diepoxide is used as the aromatic epoxy, the diluent may be an aliphatic epoxy such as diglycidyl-1,2-cyclohexanedicarboxylate, limonene oxide, 3,4-epoxycyclohexylmethyl 3,4-epoxycyclohexane carboxylate, or partially acrylated bisphenol F diepoxide. Moreover, various other polymers can also be utilized in the practice of the present invention.

In addition, various materials can be used for the Stress Compensation Layers (SCLs) described above. The material or materials used in this role will have physical properties which serve to protect the chip and package from stress and strain arising from any differences in coefficients of thermal expansion between the semiconductor die and the substrate (e.g., a PCB) to which the package may be attached. The SCL may also serve as a mask or stencil for solder ball placement. Moreover, it may also be desirable in some situations to have the SCL layer also serve as a passivation layer. Preferably, the material used for the SCL layers in devices made in accordance with the present invention will be a Si₃N₄, SiON, and/or SiO₂ may also be used. Various materials may be used as passivation layers in the devices and methodologies described herein. Passivation layers serve to protect the wafer from damage during processing. The passivation layer also serves to isolate the active sites on the wafer. It is preferred that the passivation material is a photo definable material such as BenzoCycloButene (BCB), since this allows the use of photolithographical techniques to expose the die pad. Other suitable materials for use in the passivation layer include, but are not limited to, polyimides, silicon nitride, and silicon oxide. In order to function as an effective SCL, it is typically necessary for the SCL to have a Coefficient of Thermal Expansion (CTE) that closely matches that of the adjacent die.

As shown in FIG. 3, a multilayered UBM structure is provided. In a typical embodiment, the multilayered UBM structure of the present invention comprises a barrier layer and a multilayer metal layer. The barrier seed layer 104 may be sputtered onto the dielectric layer 103. The layer 104 is preferably Ti-containing layer. For example, the Ti-containing layer 104 may be based on a variety of materials or alloys, including, without limitation, Ti, Ti—W, Ti—Cu, Ti—N, TiN—Cu and TiW—Cu alloys. In addition, the barrier seed layer 104 typically has a layer thickness within the range of about 0.3 micron to about 1 micron, preferably within the range about 0.6 micron to about 0.8 micron. In other words, a variety of materials and combinations of materials may be used in the practice of the methodologies described herein to facilitate adhesion of the UBM to the bonding pads 102. The material or materials used for this purpose may also serve other functions, such as providing a barrier seed layer 104 for electroplating operations used to form the UBM.

In the embodiment, the multilayered metal layer structure of the present invention comprises three metal layers 105, 106 and 107. The material of a first metal layer 105 may be selected by copper, shown in FIG. 3. In other words, the first metal layer 105 may be formed by employing an electroplating process with a copper solution. For example, the first metal layer 105 typically has a layer thickness within the range of about 2 micron to about 5 micron, preferably within the range about 2.5 micron to about 3.5 micron. Pure copper is especially preferred, because it can be readily electroplated using well established methods to almost any desired thickness. Copper structures with inherently low internal stress can be formed by electroplating processes. By contrast, other metal, such as nickel, is made of a second metal layer 106, shown in FIG. 2, to the thicknesses contemplated by the present invention without the occurrence of deformation or structural failure brought about by internal stresses.

Similarly, the second metal layer 106 may be formed by employing an electroplating process with a nickel solution. In addition, the second metal layer 106 typically has a layer thickness within the range of about 2 micron to about 5 micron, preferably within the range about 2.5 micron to about 3.5 micron. Copper also readily inter-diffuses with commonly used Sn (Pb free) solders during reflow to form an inter-metallic zone that reduces fracturing along the solder-UBM interface. Moreover, copper has relatively high tensile strain which ensures that any stress fractures which occur will occur in the solder portion of the solder joint rather than in the die or UBM structure. Next, another metal, such as aurum, is made of a third top metal layer 107, shown in FIG. 3. Similarly, the top metal layer 107 may be formed by employing an electroplating process with an aurum solution. In a typical embodiment, the top metal layer 107 typically has a layer thickness within the range of about 0.1 micron to about 0.5 micron, preferably within the range about 0.15 micron to about 0.35 micron.

In addition to copper, nickel and aurum, a number of other materials may be used in the construction of UBM structures of the type disclosed herein. These materials include Ag, Cr, Sn, and various alloys of these materials, including alloys of these materials with copper. In some embodiments of the UBM structures described herein, the UBM may have a multilayered structure. Thus, for example, in some embodiments, such multilayered UBMs include, but not limited to, Ti/Cu—Cu—Ni, structures or Ti/Cu—Cu—Ni—Au structures. A layer of photo-resist is coated before the E-Plating Cu/Ni/Au.

The UBM structures employed in the methods and devices described herein may take on a variety of shapes consistent with the considerations described herein. Preferably, the UBM will have an interior surface that is rounded and bowl-shaped, or is columnar or stud-shaped, and which forms a suitable receptacle for a solder composition. The use of a SCL as described herein provides for the formation of a wide variety of UBM shapes and dimensions.

A suitable flux may be used to prepare the surface of the UBM for solder application. The solder composition may then be applied by a ball drop, screen printing, or by other suitable methodologies. The solder composition is then reflowed to yield the solder bumps 109. The resulting structure may then be cleaned and cured as necessary. The placing of the solder bump 109 on the UBM can be accomplished through standard, well-known processes and hence has a good yield. Since there is no molten solder extrusion into any voids or cracks as may exist in the layers, no solder migration or electrical failures occur. There are also no adhesion issues between the UBM and pad. These structures provide low cost, high reliability wafer level packages. These scheme also provide a way to deliver a known good package using manufacturing processes compatible with wafer processing and done on the full wafer.

A variety of solders may be used in conjunction with the structures or methodologies disclosed herein. Useful solders include both eutectic and non-eutectic solders, and may be in the form of solids, liquids, pastes or powders at room temperature.

As the results of the previous figures indicate, it is not always possible to optimize one design characteristic without adversely affecting another design characteristic. As indicated by this analysis, the packages proposed herein are predicted to have a higher life time. They also overcome the drawbacks of the conventional bump design. The prior art does not have larger UBM size and only uses thinner UBM (sputtering) structure. The present invention just uses the UBM metal (sputtering seed metal and E-plating Cu/Ni/Au) with larger size and overlay by top dielectric layer to improve the adhesion strength.

As described herein, various methods have been provided which make advantageous use of a photo-definable polymer to create UBMs of various shapes and dimensions. Various structures that can be made through the use of these methods have also been provided. The methods disclosed herein can be used to create UBMs that are found to improve some of the mechanical characteristics of the solder joint. The scheme disclosed herein can also be used to create UBMs which facilitates placement of a solder ball on the UBM. These various features, taken alone or in combination, are found to have profound, beneficial effects on package reliability and lifetime.

The present invention has the advantages as follows: high reliability, avoiding the tin infiltration and improving SMT solder join, especially LGA, and improving T/C stress releasing and higher shear force. Besides, the present invention can apply to a conventional package and wafer level package etc.

The above description of the invention is illustrative, and is not intended to be limiting. It will thus be appreciated that various additions, substitutions and modifications may be made to the above described embodiments without departing from the scope of the present invention. Accordingly, the scope of the present invention should be construed in reference to the appended claims.

Having described the invention, the following is claimed:

1. An under bump metallization (UBM) structure of semiconductor device, comprising:
a substrate having a bonding pad disposed on an active surface;
a UBM adhered on said bonding pad, wherein said UBM includes lateral embedded portions and the size of said UBM is larger than the size of said bonding pad;
a dielectric layer over said UBM having opening that is smaller than said size of said UBM so as to allow said lateral embedded portions being embedded into said dielectric layer with a desired dimension; and
a conductive ball melted on said UBM within said opening defined by said dielectric layer.

2. The structure of claim 1, further comprising a metal seed layer formed under said UBM structure.

3. The structure of claim 1, further comprising a plurality of via through holes inside said lateral embedded portions of said UBM.

4. The structure of claim 1, wherein said UBM include a lower layer made of copper-containing layer.

5. The structure of claim 1, wherein said UBM include an intermediate layer made of nickel-containing layer.

6. The structure of claim 1, wherein said UBM include an upper layer made of Au-containing layer.

7. The structure of claim 1, wherein said lateral embedded portions of said UBM is longer than 30 μm.

8. The structure of claim 1, further comprising a passivation layer covered over said substrate to expose said bonding pad.

9. The structure of claim 7, wherein material of said passivation layer includes BCB, PI, SINR, or silicon nitride.

10. The structure of claim 1, wherein material of said dielectric layer includes BCB, PI, SINR or solder mask.

11. The structure of claim 1, wherein material of said dielectric layer includes SCL.

12. The structure of claim 10, wherein material of said SCL includes epoxy, a diluent, a filler, a photoinitiator or the combination.

13. The structure of claim 11, wherein said epoxy is preferably an aromatic epoxy including bisphenol A diepoxide or bisphenol F diepoxide.

14. The structure of claim 11, wherein said fillers includes borosilicate glass, quartz, silica, or spherical glass beads.

15. The structure of claim 11, wherein said diluents includes aliphatic epoxies or cycloaliphatic epoxies.
